(19) United States
(12) Patent Application Publication
(10) Pub. No.: US 2013/0334532 A1
(43) Pub. Date: Dec. 19, 2013

(54) STRESS GAUGE COMPRISED OF A PIEZOELECTRIC MATERIAL FOR USE WITH INTEGRATED CIRCUIT PRODUCTS

(71) Applicants: Xunyuan Zhang, Albany, NY (US); Vivian W. Ryan, Berne, NY (US)

(72) Inventors: Xunyuan Zhang, Albany, NY (US); Vivian W. Ryan, Berne, NY (US)

(73) Assignee: GLOBALFOUNDRIES INC., Grand Cayman (KY)

(21) Appl. No.: 13/525,664

(22) Filed: Jun. 18, 2012

(51) Int. Cl. H01L 29/84; H01L 21/768

(52) U.S. Cl. 257/48; 438/50; 257/E29.324; 257/E21.59

(57) ABSTRACT

In one example, a stress gauge for an integrated circuit product is disclosed that includes a layer of insulating material, a body positioned at least partially in the layer of insulating material, wherein the body is comprised of a material having a piezoelectric constant of at least about 0.1 pm/V, and a plurality of spaced apart conductive contacts, each of which is conductively coupled to the body.

### BACKGROUND OF THE INVENTION

1. Field of the Invention

Generally, the present disclosure relates to the manufacture of sophisticated semiconductor devices, and, more specifically, to various embodiments of a stress gauge made of a piezoelectric material for use on integrated circuit products and various methods of forming such stress gauges.

2. Description of the Related Art

As will be appreciated by those skilled in the art, a typical integrated circuit product is comprised of various active semiconductor devices, e.g., transistors, resistors, diodes, etc., that are formed in a semiconducting substrate. Thereafter, appropriate “wiring” is created to arrange the semiconductor devise in a desired circuit, e.g., a logic circuit. The wiring takes the form of multiple metallization layers, e.g., 10-14 metallization layers, that are formed above the substrate to establish the wiring pattern. Each metallization layer is comprised of conductive structures, such as conductive metal lines and/or vias, that formed in a layer of insulating material using known processing techniques.

In the manufacture of modern integrated circuits, it is necessary to provide electrical connections between the various semiconductor chips making up a microelectronic device. Depending on the type of chip and the overall device design requirements, these electrical connections may be accomplished in a variety of ways, such as, for example, by wire bonding, tape automated bonding (TAB), flip-chip bonding, and the like. In recent years, the use of flip-chip technology, wherein semiconductor chips are attached to carrier substrates, or to other chips, by means of solder balls formed from so-called solder bumps, has become an important aspect of the semiconductor processing industry. In flip-chip technology, solder balls are formed on a contact layer of at least one of the chips that is to be connected, such as, for example, on a dielectric passivation layer formed above the last metallization layer of a semiconductor chip comprising a plurality of integrated circuits. Similarly, adequately sized and appropriately located bond pads are formed on another chip, such as, for example, a carrier package, each of which corresponds to a respective solder ball formed on the semiconductor chip. The two units, i.e., the semiconductor chip and carrier substrate, are then electrically connected by “flipping” the semiconductor chip and bringing the solder balls into physical contact with the bond pads, and performing a “reflow” process so that each solder ball bonds to a corresponding bond pad. Typically, hundreds of solder bumps may be distributed over the entire chip area, thereby providing, for example, the I/O capability required for modern semiconductor chips that usually include complex circuitry, such as microprocessors, storage circuits, three-dimensional (3D) chips and the like, and/or a plurality of integrated circuits forming a complete complex circuit system.

In many processing applications, a semiconductor chip is bonded to a carrier substrate during a high temperature so-called Controlled Collapse Chip Connection (C4) solder bump reflow process. Typically, the carrier substrate material is an organic laminate, which has a coefficient of thermal expansion (CTE) that may be on the order of 4-5 times greater than the CTE of the semiconductor chip, which, in many cases, is made up primarily of silicon and silicon-based materials. Accordingly, due to the CTE mismatch between the chip and the substrate (i.e., silicon vs. organic laminate), the carrier substrate will grow more than the chip when exposed to the reflow temperature, and, as a consequence, stresses will be imposed on the chip/substrate package as the package cools and the solder bumps solidify.

During the chip packaging assembly process, after the semiconductor chip is brought into contact with the carrier substrate, the chip package is exposed to a solder bump reflow process at a reflow temperature that exceeds the melting temperature of the solder bump material. Depending on the specific solder alloy used to form the solder bumps, the reflow temperature may be upwards of 200-265° C. During the reflow process, when the material of the solder bumps is in a liquid phase, both the carrier substrate and the semiconductor chip are able to thermally “grow” in a substantially unrestrained manner, based on the respective CTE of each component. As such, both the carrier substrate and the semiconductor chip remain in an essentially flat, non-deformed condition, although each will grow by a different amount due to their different CTEs.

On the other hand, as the chip package cools, the solder bumps solidify and mechanically join the carrier or package substrate to the semiconductor chip. As the chip package continues to cool after the solder bump materials solidify, the CTE mismatch between the materials of the carrier substrate and the semiconductor chip cause the carrier substrate to shrink at a greater rate than the semiconductor chip. Typically, this difference in thermal expansion/contraction is accommodated by a combination of out-of-plane deformation of both the carrier substrate and the semiconductor chip, and some amount of shear deformation of the solder bumps. These out-of-plane deformations induce a shear and bending forces in both the carrier substrate and the semiconductor chip.

Other localized effects may occur in the semiconductor chip in areas immediately surrounding the solder bumps. The semiconductor chip may include a passivation layer formed above the last metallization layer of the product and a plurality of bond or contact pads that are conductively coupled to the “wiring” layers on the chip. Typically, an under-bump metallization (UBM) layer is formed in and above an opening in the passivation layer, and a solder bump is formed above the UBM layer and above a bond or contact pad on the semiconductor chip. As noted above, during the cool-down phase, the out-of-plane deformations of the chip package that are caused by the thermal interaction of the semiconductor chip and the carrier substrate will typically induce shear and bending loads in the chip. These shear and bending loads will result in local forces acting on each solder bump. However, since the solder material is, in general, very robust, and typically has a strength that exceeds that of the materials that make up the semiconductor chip, and in particular, the insulating materials used in the metallization layers, a fair amount of deformation energy will be absorbed by the solder bump, but typically not enough to prevent cracking in fragile metal levels. Instead, the majority of the loads will be translated through the solder bump and into the metallization layers underlying the solder bump. These translated loads will generally have the highest magnitude in an area of the metallization system that is below the edges of the solder bump.

Under the conditions outlined above, highly localized stresses may develop in one or more of the metallization layers in the integrated circuit product. Furthermore, if the stresses are of a large enough magnitude, a local failure of one or more of the metallization layers may occur below the solder bump. Typically, a failure of a given metallization layer will manifest as a delamination or a crack, and it will normally occur where the loads are highest, e.g., near the edges of the solder bump. In some cases, a crack may only occur in a single metallization layer, whereas, in other cases, and depending on many factors, a crack may propagate either deeper or shallower into the underlying metallization system, e.g., spreading from one metallization layer to another.

Delamination failures and cracks that may occur in a metallization layer below a solder bump are sometimes subject to premature failure, as the solder bump may not make a good electrical connection to the contact structures below. However, the delamination/crack defects described above are typically not detected until a final quality inspection is performed after the chip packaging processes are complete. In some cases, after the flip-chip operation has been completed, the chip package may be subjected to acoustic testing, such as C-mode acoustic microscopy (CSAM). Cracks that may be present in the metallization system of the semiconductor chip below the solder bumps will have a white appearance during the CSAM inspection process, and are, therefore, sometimes referred to as “white bumps,” “white spots,” or “ghost bumps.” White bump defects may impose a costly downside to the overall chip manufacturing process, as they likely do not occur, and hence cannot be detected, until a significant material and manufacturing investment in the chip has already occurred. Furthermore, in those instances where the assembled chip package is not subjected to CSAM inspection, undetected white bump defects may lead to reduced overall device reliability.

Moreover, recent changes and advances in the types of materials used in sophisticated semiconductor devices have also had an impact on the frequency in which white bumps occur. For example, for many years, the materials used for forming solder balls used in flip-chip technology included any one of a variety of so-called tin/lead (Sn/Pb) solders. Typically, the alloys that were used for most Sn/Pb solders have a level of ductility that enabled the Sn/Pb solder bumps to deform under the loads induced during the cool-down phase of the solder bump reflow process, thereby absorbing some of the out-of-plane deformation energy discussed above. However, in recent years, industries have generally moved away from the use of Sn/Pb solders in most commercial applications, including semiconductor processing. Accordingly, lead-free soldering materials, such as Sn/Ag (tin-silver), Sn/Cu (tin-copper), Sn/Ag/Cu (tin-silver-copper, or SAC) solders and the like, have been developed as substitute alloys for forming solder bumps on semiconductor chips. These lead-free substitute soldering materials generally have a higher material strength and lower ductility than most of the commonly-used Sn/Pb solders, and also typically require higher temperatures for reflow. As such, less deformation energy is absorbed by lead-free solder bumps, and a commensurately higher loading is imparted on the metallization system underlying the solder bumps, which may subsequently lead to the occurrence of white bump defects, as previously described.

Additionally, the development and use of dielectric materials having a dielectric constant (or k-value) of approximately 3.0 or lower—which are often referred to as “low-k dielectric materials”—has led to an increased incidence of white bumps. Typically, low-k dielectric materials have lower mechanical strength, mechanical modulus and adhesion strength than do some of the more commonly used dielectric materials having higher k-values, such as silicon dioxide, silicon nitride, silicon oxynitride and the like. As metallization systems utilize more metallization layers that are made up of low-k dielectric materials, there is a greater likelihood that the lower strength low-k materials will rupture when exposed to the loads that are imposed on the metallization layers underlying the solder bumps, thus leading to delaminations and cracks, i.e., white bump defects. In particular, cracks tend to occur, or at least initiate, in the low-k metallization layers that are closest to the upper surface of the a semiconductor chip, i.e., closest to the last metallization layer, as the deformation energy is greatest near the upper surface, and lessens in lower metallization levels. Furthermore, it appears that the type of white bump problems described above are even further exacerbated in metallization layers comprised of ultra-low-k (ULK) materials having k-values of approximately 2.7 or lower.

It should be noted that, while the “white bump” problems discussed above were discussed in the context of flip-chip packaging problems, the issues identified above are equally applicable to other chip package configurations, such as 3D-chips and the like. Furthermore, white bump problems are not only limited to chip packaging connections that are made using traditional solder ball bump structures. For example, the thermal interactions described above may also occur when other types of bump structures, such as pillar bump structures, are used to facilitate the electrical connections between the semiconductor chip and the carrier substrate. Pillar bump structures, also sometimes referred to as post bump structures, are typically made up of a highly conductive metal, such as copper, gold, silver and the like, or alloys thereof, which may provide certain advantages over traditional solder ball bump structures. For example, pillar bumps may permit a higher standoff between the chip and the substrate, thereby facilitating easier underfilling after the bonding operation. Furthermore, highly conductive pillar bumps, such as copper pillar bumps, may also provide better overall thermal and/or electrical performance. However, pillar bump structures generally also include small solder caps, which, as with the solder ball bump structures described above, must also be exposed to a high temperature reflow process so as to provide the final electrical connection to a carrier substrate, during which time the above-described thermal interactions will occur.

Moreover, due to the relatively lower mechanical strength of the low-k materials, a relatively thin layer of a denser insulating material, such as silicon nitride, is formed above the low-k material in an effort to prevent migration of copper, a metal that is commonly used to form the conductive lines and vias in an integrated circuit product. Typically, due to a mismatch between the coefficient of thermal expansion (CTE) of the denser material and the low-k material, the interface between the denser insulating material and the low-k material is subject to a very large stress differential, with a corresponding increase in the likelihood that a crack may start at the highly-stressed interface. However, typically, such cracks are not detected until after the chip is packaged. Thus, under current practice, it is not possible to determine whether a crack occurred before chip packaging or as a result of the chip packaging activities.

The present disclosure is directed to various embodiments of a stress gauge made of a piezoelectric material that may solve or at least reduce one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to various embodiments of a stress gauge made of a piezoelectric material for use on integrated circuit products and various methods of forming such stress gauges. In one example, a stress gauge for an integrated circuit product is disclosed that includes a layer of insulating material, a body positioned at least partially in the layer of insulating material, wherein the body is comprised of a material having a piezoelectric constant of at least about 0.1 pm/v and a plurality of spaced apart conductive contacts, each of which is conductively coupled to the body. In some applications, the body may be made of aluminum nitride or GaN, a ferroelectric ceramic, or a piezoelectric polymer.

In another example, the integrated circuit product includes a layer of insulating material, a body that is positioned at least partially in the layer of insulating material, the body being comprised of aluminum nitride or GaN, a ferroelectric ceramic, or a piezoelectric polymer, wherein the body has at least first and second side surfaces, a top surface and a bottom surface and wherein the body is adapted to generate a first voltage that corresponds to a first stress applied to the body in a horizontal direction and a second voltage that corresponds to a second stress applied to the body in a vertical direction, and first, second, third and fourth spaced-apart conductive contacts that are conductively coupled to the first side surface, the second side surface, the bottom surface and the top surface, respectively, of the body.

One illustrative method disclosed herein of forming a stress gauge for an integrated circuit product includes forming a trench in a layer of insulating material, forming a first layer of a conductive contact material above the layer of insulating material and in the trench, performing at least one etching process on the first layer of conductive contact material to define a bottom conductive contact and at least two side contacts from the first layer of conductive contact material, depositing a piezoelectric material having a piezoelectric constant of at least about 0.1 pm/V in the trench above the bottom conductive contact and between the at least two side contacts, forming a second layer of a conductive contact material on the piezoelectric material and performing at least one process operation to form a top conductive contact from the second layer of conductive contact material, wherein the top conductive contact is conductively coupled to the piezoelectric material.

### BRIEF DESCRIPTION OF THE DRAWINGS

The disclosure may be understood by reference to the following description taken in conjunction with the accompanying drawings, in which like reference numerals identify like elements, and in which:

FIGS. 1A-1C depict various illustrative embodiment of a stress gauge disclosed herein for use on integrated circuit products;

FIG. 2 depicts one illustrative embodiment of a stress gauge disclosed herein that is operatively coupled to two illustrative volt meters; and

FIGS. 3A-3G depict one illustrative process flow disclosed herein for forming one illustrative embodiment of a stress gauge disclosed herein.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

In general, the present disclosure is directed to a stress gauge that may be formed at any location and at any level in an integrated circuit product. The stress gauges disclosed herein may be employed to detect stress levels in layers of material, such as layers of insulating material that are commonly employed in integrated circuit products. The stress gauges may be employed for a variety of purposes, such as, for example, as part of the product design process, to determine and evaluate stress levels in one or more layers of material so as to identify potential areas where cracks may form and/or to identify when cracks have formed or may be about to form in production or finished integrated circuit products. The gauges disclosed herein may also be used to improve on packaging processes (minimize applied external forces) or as “warranty monitors” whereby the manufacturer may be able to determine if a customer exceeded allowable specification limits during assembly or during use of the product. As will be recognized by those skilled in the art after a complete reading of the present application, the stress gauges disclosed herein may be employed in any type of integrated circuit product, e.g., logic products, memory products, ASICs, system-on-chip products, etc. With reference to the attached figures, various illustrative embodiments of the methods and devices disclosed herein will now be described in more detail.

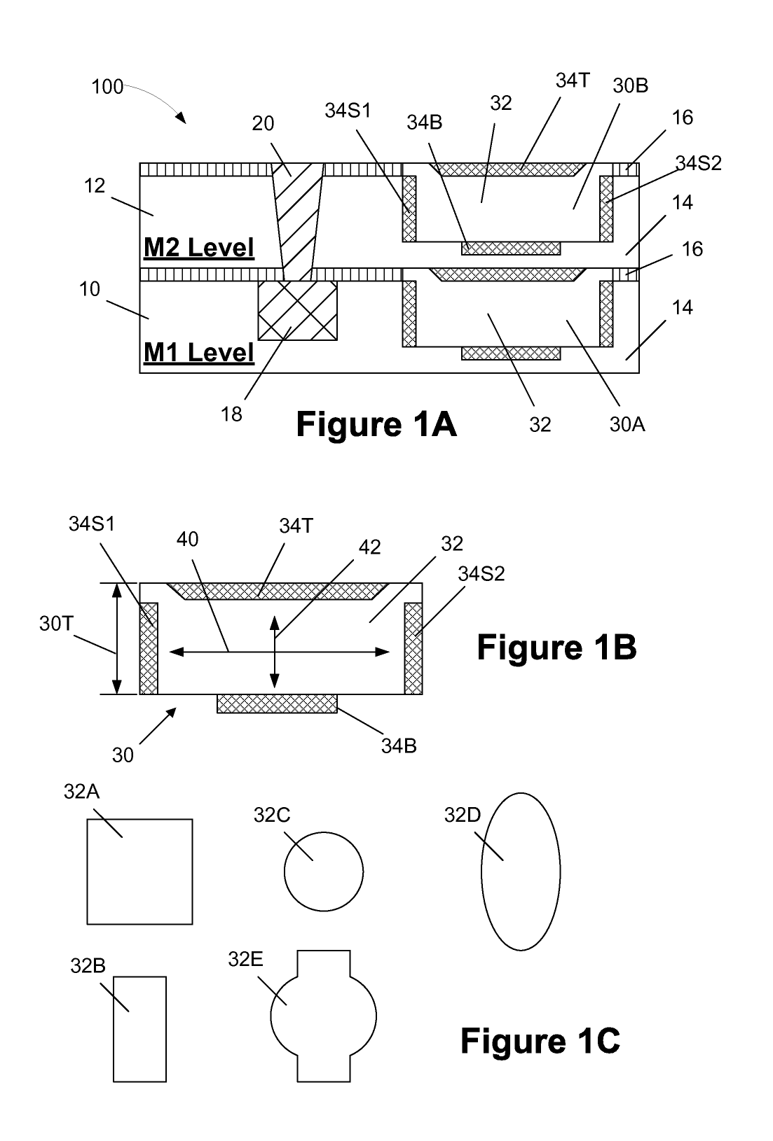

FIGS. 1A-1C depict various illustrative embodiments of a stress gauge as disclosed herein. FIG. 1A depicts a portion of an illustrative integrated circuit product or device 100 at an intermediate stage of manufacturing. As will be appreciated by those skilled in the art, a typical integrated circuit device 100 is comprised of various active semiconductor devices, e.g., transistors, resistors, diodes, etc., that are formed in a semiconducting substrate. Thereafter, appropriate “wiring” is created to arrange the semiconductor device in a desired circuit, e.g., a logic circuit. The wiring takes the form of multiple metallization layers, e.g., 10-14 metallization layers, that are formed above the substrate to establish the wiring pattern. Each metallization layer is comprised of conductive structures, such as conductive metal lines and/or vias, that formed in a layer of insulating material using known processing techniques.

With reference to FIG. 11A, two illustrative metallization layers or levels—“M1” and “M2”—of the integrated circuit product 100 are depicted. The metallization layers 10, 12 depicted in FIG. 1A are intended to be representative in natures as the stress gauges disclosed herein may be formed at any metallization level and at any location on the device 100. As shown in FIG. 1A, each of the metallization layers 10, 12 is comprised of a layer of insulating material 14 and an etch stop layer 16. In the depicted example, an illustrative conductive line 18 is formed in the metallization layer 10 and an illustrative conductive via 20 is formed in the metallization layer 12. The layers of insulating material 14 and the etch stop layer 16 are also intended to be representative in nature. That is, the product 100 may use any type of insulating material, e.g., silicon dioxide, a low-k insulating material (k value less than about 3.5), etc. Similarly, the etch stop layer 16 may be comprised of a variety of different materials, e.g., silicon nitride. The layers of insulating material 14 and the etch stop layers 16 may be formed to any desired thickness and they may be formed using traditional manufacturing processes, e.g., chemical vapor deposition (CVD), atomic layer deposition (ALD), etc. The conductive structures 18, 20 are also intended to be representative in nature in that they should be understood to represent any type of conductive structure that is employed as part of the wiring circuitry for the product 100. The conductive structures 18, 20 may be comprised of a variety of different materials, e.g., copper, aluminum, etc., and they may be formed using traditional techniques. Moreover, as will be appreciated by those skilled in the art after a complete reading of the present application, the stress gauges disclosed herein may be positioned in layers of insulating material where there are no such conductive structures or where any such conductive structures are located a great distance away from the stress gauge. Thus, the type of insulating material employed in a product 100 as well as the existence or proximity of any conductive structures to the stress gauges disclosed herein should not be considered to be a limitation of the presently disclosed inventions.

In the example depicted herein, a first stress gauge 30A is formed in the metallization layer 10 and a second stress gauge 30B is formed in the metallization layer 12. The generic reference number “30” will be used to discuss the structure of the illustrative stress gauges 30A, 30B depicted in FIG. 1A. As noted earlier, the stress gauges 30 disclosed herein may be employed at any level or at any location on an integrated circuit product 100. Any number of stress gauges 30 may be employed on an integrated circuit product 100. The stress gauges 30 may be concentrated in various areas, e.g., corner regions of the device 100, or they may be spread randomly throughout the device 100, both vertically and horizontally.

FIG. 1B is an enlarged drawing of the illustrative stress gauge 30 disclosed herein. As shown therein, the stress gauge 30 is comprised of a body 32, side contacts 34S1, 34S2, a bottom contact 34B and a top contact 34T. The thickness 30T of the stress gauge 30 may vary depending upon the particular application. In one illustrative embodiment, the thickness may fall within the range of about 10 nm-10 μm. Each of the contacts 34S1, 34S2, 34B and 34T are conductively coupled to the body 32 and the contacts may be of any desired size and configuration and they may manufactured from any desired conducting material, e.g., tungsten, aluminum, tantalum, etc. In some applications, a stress gauge 30 may be employed with less than the four illustrative contacts depicted herein, e.g., a stress gauge 30 may only have the side contacts 34S1 and 34S2. As described more fully below, the body 32 of the stress gauge 30 is comprised of a piezoelectric material that will permit measurement of horizontal (in-plane) stress 40 and vertical (out-of-plane) stress 42. In one illustrative embodiment, the body 32 may be made of a piezoelectric material having a piezoelectric constant of at least about 0.1 pico meters/volt (pm/v). For example, the body 32 may be made of material such as aluminum nitride (AlN), GaN, a ferroelectric ceramic, or a piezoelectric polymer, etc. The piezoelectric material may be either doped or undoped. In one illustrative embodiment, the body 32 may be comprised of aluminum nitride that is doped with scandium (Sc) or Cr or any transition metal nitride, such that the dopant concentration is about 20-45%. The dopant material may be introduced into the piezoelectric material via an in situ doping process or by ion implantation. Introducing the dopant increases the piezoelectric constant of the piezoelectric material. For example, in the case of aluminum nitride, which has a piezoelectric constant of about 6 pm/v in an undoped condition, when it is doped with scandium in a concentration of about 20-45%, the piezoelectric constant increases to about 25 pm/v.

The stress gauge 30 may be of any desired shape or configuration, and it may vary depending upon the particular application. FIG. 1C depicts various illustrative plan views of the stress gauge 30. More specifically, the body 32 of the stress gauge 30 may have a generally square configuration 32A, a rectangular configuration 32B, a circular configuration 32C, an oval configuration 32D, or a composite configure 32E (e.g., a combination of a rectangle and a circle), etc. Moreover, a particular integrated circuit device 100 may contain multiple stress gauges 30 having different configurations. Additionally, the overall size of the stress gauge 30 may vary depending upon the particular application. For example, in the case where the body 32 of the stress gauge 30 has a rectangular configuration 32B, the stress gauge 30 may have a length of about 0.1-60 μm and a width of about 40 nm-20 μm.

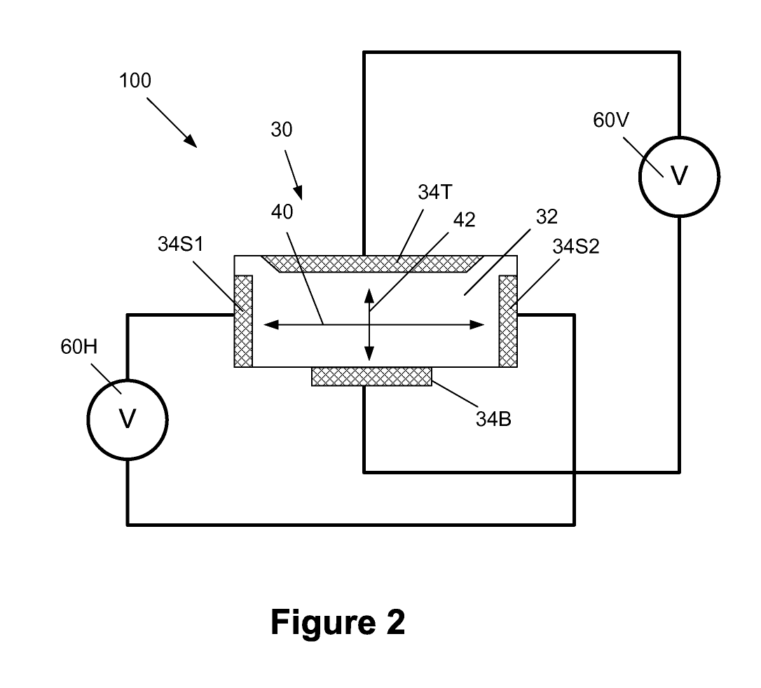

FIG. 2 is a schematic depiction of the integrated circuit device 100 wherein the illustrative stress gauge 30 is comprised of first and second electrically isolated electrical circuits that are adapted to be operatively coupled to first and second electrical instruments, e.g., voltmeters 60V, 60 H. More specifically, in the depicted embodiment, the first voltmeter 60V is operatively coupled to the first circuit and thus to the top and bottom contacts 34T, 34B, while the second voltmeter 60 H is operatively coupled to the second circuit and thus the two side contacts 34S1, 34S2. Using this arrangement, the horizontal (in-plane) stress 40 and the vertical (out-of-plane) stress 42 can both be measured independently. As to the general theory of operation of the stress gauge 30, when the piezoelectric material of the body 32 is stressed, it produces a voltage drop that can be sensed and calibrated with a corresponding stress level. By detecting the stress levels (or changes in stress levels) in one or more of the stress gauges 30, the presence of a crack or the likelihood of a crack forming in a layer of insulating material or in a region of the integrated circuit product can be more readily detected and appropriate corrective actions can be taken. Of course, electrical instrumentation other than the illustrative voltmeters 60V, 60 H may be employed with the stress gauge 30, e.g., current meters could be employed in lieu of the illustrative voltmeters.

As discussed above, when stressed in either the horizontal 40 or vertical 42 directions, the piezoelectric material will generate a voltage that can be measured using the voltmeters 60 H, 60V, respectively. The voltage generated is determined by the following formula:

V=C_{P}*P* (t/ε) where

V—measured voltage (volts)

Cp—piezoelectric constant in the z direction

P—the stress applied on the piezoelectric material (MPa)

t—the thickness of the piezoelectric material in the considered stress direction (nm)

ε—vacuum permittivity 8.85 e −12 (farads/meter)

The stress gauge 30 disclosed herein is capable of generating relative large voltage levels using the pressures and size materials that may be readily found in integrated circuit products and the manufacture of such products. As a specific example, in the case where the body 32 of the stress gauge 30 has a thickness 30T of about 100 nm and is made of undoped aluminum nitride (with a piezoelectric constant of about 6 pm/v), and using a stress level of about 10 MPa, which is a typical stress value commonly found in chip packaging situations, the voltage may be about 1 volt, a relatively large number in comparison to voltage levels generated by prior art stress gauges. The relatively large voltage levels that may be generated using the stress gauge 30 disclosed herein facilitates detection of even small changes in voltage level, thereby permitting some heretofore unknown granularity into the detection of crack initiation and propagation investigations. The stress gauge 30 disclosed herein permits virtually real-time monitoring of changes in stress levels at multiple locations within multiple layers. By providing a number of such stress gauges 30 on an integrated circuit product, the detection of the exact source and cause of product failures may be more easily determined. For example, multiple stress gauges 30 may be positioned around sensitive or critical circuitry in, for example, a three dimensional array, so as to determine/investigate a true 3-dimensional stress map in the area of interest. In one particular example, the stress gauges 30 may be positioned in the vicinity underneath the tensile stress side of the solder bumps used in chip-packaging. Another illustrative application would be to employ one or more of the stress gauges 30 on the lower metal levels of an integrated circuit device in the vicinity of through-silicon via commonly found in so-called via-middle schemes. Additionally, in the case where the body 32 is made of aluminum nitride, it is virtually inert as it relates to the processes and materials used in typical back-end-of-the-line processing activities.

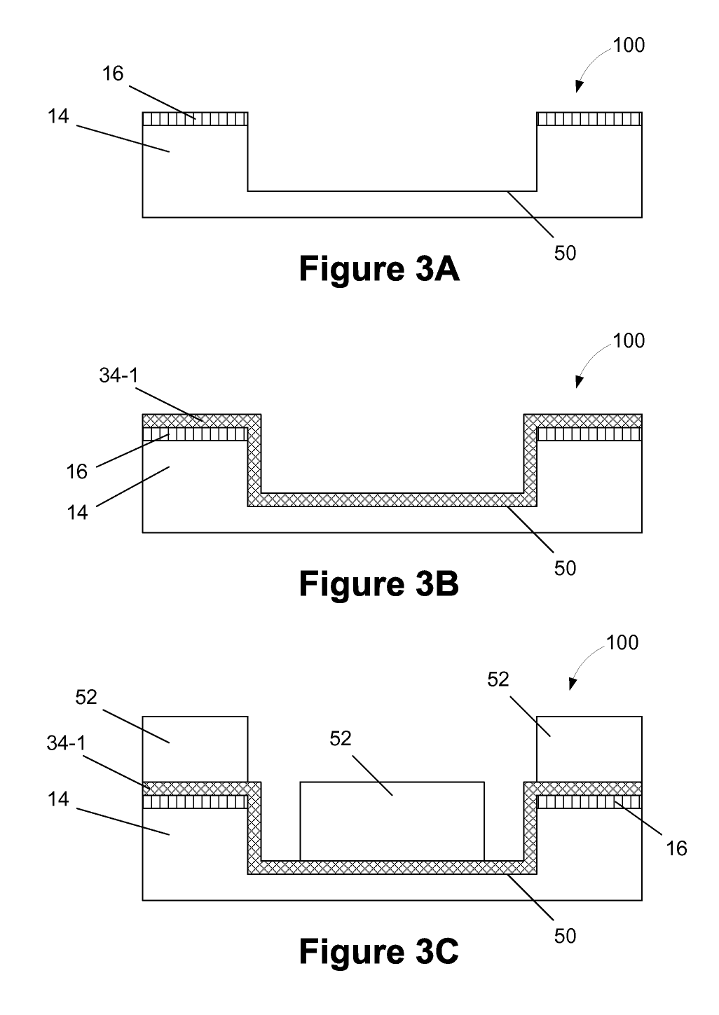

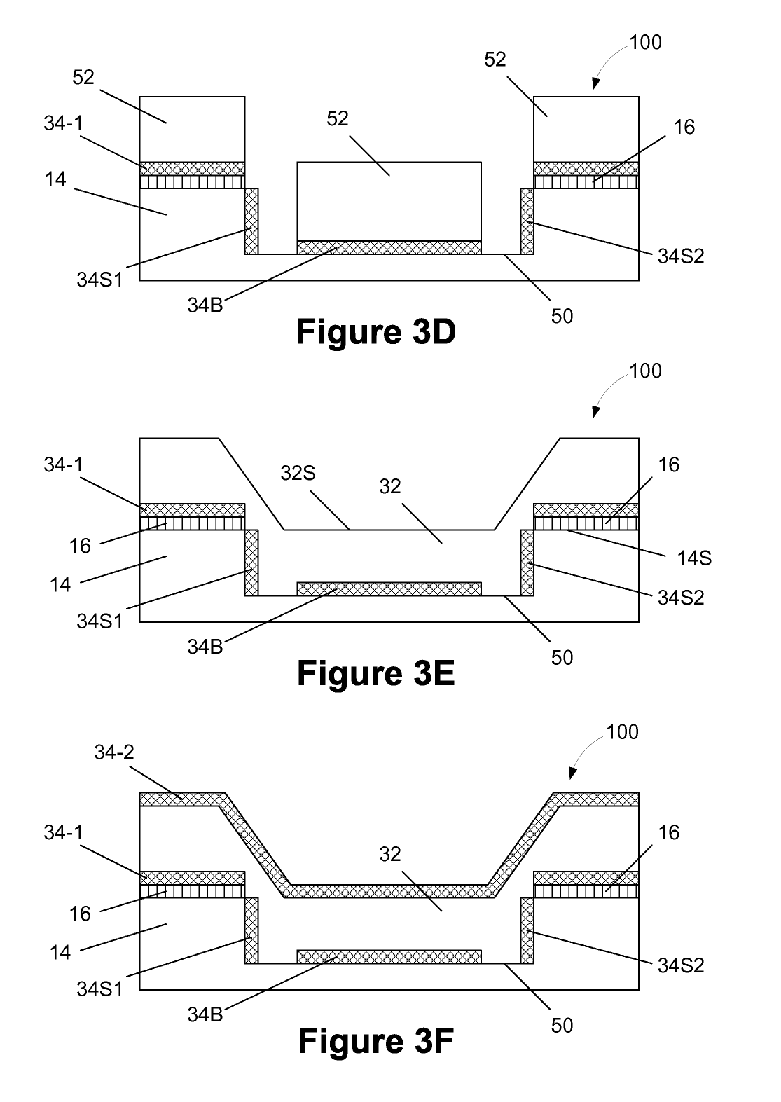

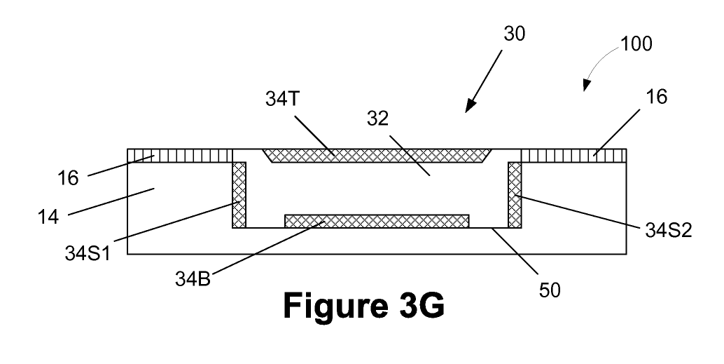

FIGS. 3A-3G depict one illustrative process flow that may be employed to form one illustrative embodiment of the stress gauge 30 disclosed herein. As shown in FIG. 3A, a trench 50 is formed in a layer of insulating material 14. The trench 50 may be formed by forming a patterned mask layer (not shown), e.g., a patterned photoresist mask, above the etch stop layer 16. Thereafter, one or more etching processes may then be performed through the patterned mask layer to define the trench 50. The depth and width of the trench 50 may vary depending upon the particular application. After the trench 50 is formed, the patterned mask layer may be removed by performing a plasma ashing process.

Next, as shown in FIG. 3B, a first layer of conductive contact material 34-1 is conformably deposited on the device 100. Portions of the first layer of conductive contact material 34-1 will eventually become the side contacts 34S1, 34S2. The first layer of conductive contact material 34-1 may be comprised of any metal or metal-containing compound, e.g., tungsten, aluminum, titanium, etc., its thickness may vary, and it may be formed by performing, for example, a physical vapor deposition (PVD) process.

Then, as shown in FIG. 3C, a patterned mask layer 52, e.g., a patterned photoresist mask, is formed above the device 100. In one embodiment, the patterned mask layer 52 may be formed using traditional photolithography tools and techniques.

FIG. 3D depicts the device 100 after an etching process has been performed through the patterned mask layer 52 on the first layer of conductive contact material 34-1. This etching process results in the definition of the side contacts 34S1 and 34S2 and the bottom contact 34B. After the etching process is performed, the patterned mask layer 52 may be removed.

Next, as shown in FIG. 3E, the piezoelectric material of the body 32 is deposited above the device 100. The piezoelectric material may be formed by performing an ALD or CVD process using the appropriate precursors. In one embodiment, the deposition process is controlled such that the upper surface 32S of the piezoelectric material within the trench 50 is approximately level with the upper surface 14S of the layer of insulating material 14.

Then, as shown in FIG. 3F, a second layer of conductive contact material 34-2 is conformably deposited on the device 100. A portion of the second layer of conductive contact material 34-2 will eventually become the top contact 34T. The second layer of conductive contact material 34-2 may be comprised of the same materials and made in the same manner as described above for the first layer of conductive contact material 34-1. However, the first layer of conductive contact material 34-1 and the second layer of conductive contact material 34-2 need not be made of the same material in all applications.

Next, as shown in FIG. 3G, one or more chemical mechanical polishing (CMP) processes may be performed to remove the materials positioned above the etch stop layer 16. This process results in the definition of the top contact 34T and completes the fabrication of the illustrative stress gauge 30.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. An integrated circuit product, comprising:
a layer of insulating material;
a body positioned at least partially in said layer of insulating material, said body comprised of a material having a piezoelectric constant of at least about 0.1 pm/V; and
a plurality of spaced apart conductive contacts, each of which is conductively coupled to the body.

2. The product of claim 1, wherein said layer of insulating material is comprised of silicon dioxide or a low-k insulating material.

3. The product of claim 1, wherein said body is comprised of one of aluminum nitride or GaN, or a ferroelectric ceramic, or a piezoelectric polymer.

4. The product of claim 1, wherein said body has a rectangular, square, round or oval configuration when viewed from above.

5. The product of claim 1, wherein said body has a thickness that falls within the range of about 10 nm-10 μm.

6. The product of claim 1, wherein, said body has at least first and second side surfaces, a top surface and a bottom surface and wherein said plurality of spaced apart conductive contacts comprises at least a first side contact conductively coupled to said first side surface, a second side contact conductively coupled to said second side surface, a third conductive contact conductively coupled to said bottom surface and a fourth conductive contact conductively coupled to said top surface.

7. The product of claim 1, further comprising a first circuit and a second circuit that are electrically isolated from one another, wherein said first circuit is conductively coupled to said first and second side contacts and said second circuit is conductively coupled to said third and fourth conductive contacts.

8. The product of claim 7, wherein said first and second circuits are adapted to be operatively coupled to first and second voltmeters, respectively.

9. The product of claim 1, wherein said body is adapted to generate a voltage that corresponds to a stress applied to said body in at least one of a horizontal or vertical direction.

10. The product of claim 1, wherein said body is adapted to generate a first voltage that corresponds to a first stress applied to said body in a horizontal direction and a second current that corresponds to a second stress applied to said body in a vertical direction.

11. The product of claim 1, wherein said plurality of spaced apart conductive contacts comprises at least four spaced apart conductive contacts, each of which is conductively coupled to said body.

12. The product of claim 11, further comprising a first circuit and a second circuit that are electrically isolated from one another, wherein said first circuit is conductively coupled to two of said four conductive contacts and said second circuit is conductively coupled to the other two of said four conductive contacts.

13. The product of claim 12, wherein said first and second circuits are adapted to be operatively coupled to first and second voltmeters, respectively.

14. An integrated circuit product, comprising:
a layer of insulating material;
a body positioned at least partially in said layer of insulating material, said body being comprised of one of aluminum nitride or GaN, or a ferroelectric ceramic, or a piezoelectric polymer, wherein said body has at least first and second side surfaces, a top surface and a bottom surface and wherein said body is adapted to generate a first voltage that corresponds to a first stress applied to said body in a horizontal direction and a second voltage that corresponds to a second stress applied to said body in a vertical direction;
a first side contact conductively coupled to said first side surface of said body;
a second side contact conductively coupled to said second side surface of said body;
a third conductive contact conductively coupled to said bottom surface of said body; and
a fourth conductive contact conductively coupled to said top surface of said body.

15. The product of claim 14, wherein said layer of insulating material is comprised of silicon dioxide or a low-k insulating material.

16. The product of claim 14, further comprising a first circuit and a second circuit that are electrically isolated from one another, wherein said first circuit is conductively coupled to said first and second side contacts and said second circuit is conductively coupled to said third and fourth conductive contacts.

17. The product of claim 16, wherein said first and second circuits are adapted to be operatively coupled to first and second voltmeters, respectively.

18. A method of forming a stress gauge for an integrated circuit product, the method comprising:
forming a trench in a layer of insulating material;
forming a first layer of a conductive contact material above said layer of insulating material and in said trench;
performing at least one etching process on said first layer of conductive contact material to define a bottom conductive contact and at least two side contacts from said first layer of conductive contact material;
depositing a piezoelectric material having a piezoelectric constant of at least about 0.1 pm/V in said trench above said bottom conductive contact and between said at least two side contacts;
forming a second layer of a conductive contact material on said piezoelectric material; and
performing at least one process operation to form a top conductive contact from said second layer of conductive contact material, wherein said top conductive contact is conductively coupled to said piezoelectric material.

19. The method of claim 18, further comprising forming a first circuit and a second circuit that are electrically isolated from one another, wherein said first circuit is conductively coupled to said at least two side contacts and said second circuit is conductively coupled to said bottom and top conductive contacts.

20. The method of claim 19, wherein said first and second circuits are adapted to be operatively coupled to first and second voltmeters, respectively.

21. The method of claim 18, wherein performing said at least one process operation to form said top conductive contact comprises performing at least one chemical mechanical polishing process to remove portions of said piezoelectric material and portions of said second layer of conductive contact material that are positioned above said layer of insulating material and outside of said trench.

22. The method of claim 18, wherein said first and second layers of conductive contact material are comprised of different materials.

23. A method of forming a stress gauge for an integrated circuit product, the method comprising:
forming a trench in a layer of insulating material;
forming a first layer of a conductive contact material above said layer of insulating material and in said trench;
performing at least one etching process on said first layer of conductive contact material to define a bottom conductive contact and at least two side contacts from said first layer of conductive contact material;
depositing a piezoelectric material comprised of one of aluminum nitride or GaN, or a ferroelectric ceramic, or a piezoelectric polymer in said trench above said bottom conductive contact and between said at least two side contacts;
forming a second layer of a conductive contact material on said piezoelectric material; and
performing at least one chemical mechanical polishing process to remove portions of said piezoelectric material and portions of said second layer of conductive contact material that are positioned above said layer of insulating material and outside of said trench to thereby form a top conductive contact from said second layer of conductive contact material, wherein said top conductive contact is conductively coupled to said piezoelectric material.

24. The method of claim 23, further comprising forming a first circuit and a second circuit that are electrically isolated from one another, wherein said first circuit is conductively coupled to said at least two side contacts and said second circuit is conductively coupled to said bottom and top conductive contacts.

25. The method of claim 24, wherein said first and second circuits are adapted to be operatively coupled to first and second voltmeters, respectively.
